(19) United States
(12) Patent Application Publication
(10) Pub. No.: US 2024/0131653 A1
(43) Pub. Date: Apr. 25, 2024

(54) POLISHING PAD AND METHOD FOR MANUFACTURING POLISHING PAD

(71) Applicant: FUJIBO HOLDINGS, INC., Tokyo (JP)

(72) Inventors: Teppei TATENO, Ehime (JP); Hiroshi KURIHARA, Ehime (JP); Satsuki YAMAGUCHI, Ehime (JP); Yamato TAKAMIZAWA, Ehime (JP); Keisuke OCHI, Ehime (JP); Tetsuaki KAWASAKI, Ehime (JP)

(73) Assignee: FUJIBO HOLDINGS, INC., Tokyo (JP)

(21) Appl. No.: 18/278,402

(22) PCT Filed: Mar. 28, 2022
(86) PCT No.: PCT/JP2022/015347

§ 371 Date: Aug. 21, 2023

(30) Foreign Application Priority Data
Mar. 29, 2021 (JP) 2021-056760

(51) Int. Cl. B24B 37/22

(52) U.S. Cl. CPC B24B 37/22

(57) ABSTRACT

This polishing pad has a polishing layer that comprises a polyurethane resin foam derived from an isocyanate-terminated prepolymer and a curing agent, wherein: the distance between hard segments in the polishing layer as measured by small-angle X-ray scattering is 9.5 nm or less; or the ratio (NC80/CC80) of the content proportion by weight (NC80) of an amorphous phase in the polishing layer as measured by pulse NMR at 80° C. to the content proportion by weight (CC80) of a crystalline phase in the polishing layer as measured by pulse NMR at 80° C. is 2.6-3.1, and the ratio (NC40/CC40) of the content proportion by weight (NC40) of an amorphous phase in the polishing layer as measured by pulse NMR at 40° C. to the content proportion by weight (CC40) of a crystalline phase in the polishing layer as measured by pulse NMR at 40° C. is 0.5-0.9.

### TECHNICAL FIELD

The present invention relates to a polishing pad. In detail, the present invention relates to a polishing pad that can be suitably used to polish optical materials, semiconductor wafers, semiconductor devices, hard disk substrates and the like.

### BACKGROUND ART

As a polishing method for flattening the surfaces of optical materials, semiconductor wafers, semiconductor devices and hard disk substrates, a chemical mechanical polishing (CMP) method has been ordinarily used.

The CMP method will be described using FIG. 1. As shown in FIG. 1, a polishing device 1 configured to perform the CMP method is provided with a polishing pad 3, and the polishing pad 3 includes a polishing layer 4 that is a layer that comes into contact with an item to be polished 8 held with a holding surface plate 16 and performs polishing and a cushion layer 6 that supports the polishing layer 4. The polishing pad 3 is driven to rotate in a state where the item to be polished 8 is pressed and polishes the item to be polished 8. At that time, a slurry 9 is supplied between the polishing pad 3 and the item to be polished 8. The slurry 9 is a mixture (dispersion) of water and a variety of chemical components or fine hard abrasive grains and enhances the polishing effect due to a relative movement between the item to be polished 8 and the chemical components or the abrasive grains in the slurry that are made to flow. The slurry 9 is supplied to and discharged from a polishing surface through grooves or holes.

Incidentally, in the polishing of semiconductor devices, it is ordinary to use polishing pads in which a hard polyurethane material obtained by reacting a prepolymer containing an isocyanate component (toluene diisocyanate (TDI) or the like) and a high-molecular-weight polyol (poly(oxytetramethylene) glycol (PTMG) or the like) and a diamine-based curing agent (4,4′-methylene-bis(2-chloroaniline) (MOCA) or the like) is used as the polishing layer 4. The high-molecular-weight polyol that is contained in the prepolymer forms a soft segment of urethane, and PTMG that is easy to handle or exhibits appropriate rubber elasticity has been thus far well used as the high-molecular-weight polyol.

However, recently, in association with cable miniaturization in semiconductor devices, in conventional polishing pads, there are cases where the step elimination performance or the defect performance is not sufficient, and studies are underway to use polyols other than PTMG as the high-molecular-weight polyol.

As literature in which the above-described problem has been studied, Patent Literature 1 discloses a polishing pad in which polypropylene glycol (PPG) is used as the high-molecular-weight polyol in the prepolymer, whereby the step elimination performance is high and the number of scratches is small.

In addition, Patent Literature 2 discloses a polishing pad in which a mixture of PPG and PTMG is used as the high-molecular-weight polyol in the prepolymer, whereby the defect rate has been reduced.

### CITATION LIST

### Patent Literature

[Patent Literature 1]
Japanese Patent Laid-Open No. 2020-157415
[Patent Literature 2]
Japanese Patent Laid-Open No. 2011-040737

### SUMMARY OF INVENTION

### Technical Problem

However, the polishing pad described in Patent Literature 1 had a problem in that the wear resistance of a polishing layer was poor and the life of the polishing pad was short. In addition, the polishing pad described in Patent Literature 2 had a problem in that the step elimination performance or the defect performance was not sufficient.

The present invention has been made in consideration of the above-described problems, and an objective of the present invention is to provide a polishing pad being excellent in terms of step elimination performance or defect performance and, furthermore, having excellent wear resistance.

### Solution to Problem

As a result of intensive studies, the present inventors found that, in a case where a material that is used for a polishing layer in a polishing pad has a structure in which the distance between hard segments is a specific length, the polishing pad becomes excellent in terms of step elimination performance or defect performance and, furthermore, becomes excellent in terms of wear resistance and reached the present invention.

In addition, the present inventors studied the proportions of a crystalline phase, an intermediate phase and an amorphous phase in the polishing layer and found that, when the proportions of the crystalline phase and the amorphous phase at 80° C. are within a specific range, and the proportions of the crystalline phase and the amorphous phase at 40° C. are within a specific range, the above-described problems can be solved and reached the present invention.

That is, the present invention includes the followings.
[1] A polishing pad having a polishing layer composed of a polyurethane resin foam derived from an isocyanate-terminated prepolymer and a curing agent, in which a distance between hard segments in the polishing layer as measured by small-angle X-ray scattering is 9.5 nm or less.
[2] The polishing pad according to [1], in which the isocyanate-terminated prepolymer includes a polyisocyanate compound-derived configuration unit and a high-molecular-weight polyol-derived configuration unit, and the high-molecular-weight polyol-derived configuration unit is composed of at least a polypropylene glycol configuration unit and a polyester diol configuration unit.
[3] The polishing pad according to [2], in which there is less than 60 weight % of the polypropylene glycol configuration unit with respect to the high-molecular-weight polyol-derived configuration unit.
[4] The polishing pad according to [2], in which a polyester diol for forming the polyester diol configuration unit has a number-average molecular weight of 600-2500.
[5] The polishing pad according to [1], in which an average bubble diameter in the polyurethane resin foam is 5 μm or more and less than 20 μm.
[6] The polishing pad according to [1], in which the isocyanate-terminated prepolymer has an NCO equivalent of 500-600.
[7] The polishing pad according to [1], in which the distance between the hard segments in the polishing layer as measured by small-angle X-ray scattering is 3.0-9.5 nm.
[8] A method for manufacturing a polishing pad having a polishing layer composed of a polyurethane resin foam, the method including
a step of mixing and reacting an isocyanate-terminated prepolymer and a curing agent to obtain the polyurethane resin foam and
a step of molding the polyurethane resin foam into a shape of the polishing layer,
in which a distance between hard segments in the polishing layer as measured by small-angle X-ray scattering is 9.5 nm or less.
[9] The method for manufacturing a polishing pad according to [8], in which an unexpanded balloon is made to coexist at the time of mixing the isocyanate-terminated prepolymer and the curing agent.
[10] A polishing pad having a polishing layer composed of a polyurethane resin foam derived from an isocyanate-terminated prepolymer and a curing agent,
in which a ratio (NC80/CC80) of a content proportion by weight (NC80) of an amorphous phase in the polishing layer as measured by pulse NMR at 80° C. to a content proportion by weight (CC80) of a crystalline phase in the polishing layer as measured by pulse NMR at 80° C. is 2.6-3.1, and
a ratio (NC40/CC40) of a content proportion by weight (NC40) of the amorphous phase in the polishing layer as measured by pulse NMR at 40° C. to a content proportion by weight (CC40) of the crystalline phase in the polishing layer as measured by pulse NMR at 40° C. is 0.5-0.9.
[11] The polishing pad according to [10], in which a numerical value that is obtained from Expression (1) below is larger than 1.9 and smaller than 2.2.

[Expression 1]

(NC80/CC80)−(NC40/CC40) (1)
[12] The polishing pad according to [10], in which the CC80 is 19.0-22.0 weight %.
[13] The polishing pad according to [10], in which the NC40 is 22.0-27.0 weight %.
[14] The polishing pad according to [10], in which the isocyanate-terminated prepolymer includes a polyisocyanate compound-derived configuration unit and a high-molecular-weight polyol-derived configuration unit, and
the high-molecular-weight polyol-derived configuration unit is composed of at least a polypropylene glycol configuration unit and a polyester diol configuration unit.
[15] The polishing pad according to [14], in which there is less than 60 weight % of the polypropylene glycol configuration unit with respect to the high-molecular-weight polyol-derived configuration unit.
[16] The polishing pad according to [14] or [15], in which a polyester diol for forming the polyester diol configuration unit has a number-average molecular weight of 600-2500.
[17] The polishing pad according to [10], in which the isocyanate-terminated prepolymer has an NCO equivalent of 500-600.
[18] A method for manufacturing a polishing pad having a polishing layer composed of a polyurethane resin foam, the method including
a step of mixing and reacting an isocyanate-terminated prepolymer and a curing agent to obtain the polyurethane resin foam and
a step of molding the polyurethane resin foam into a shape of the polishing layer,
in which a ratio (NC80/CC80) of a content proportion by weight (NC80) of an amorphous phase in the polishing layer as measured by pulse NMR at 80° C. to a content proportion by weight (CC80) of a crystalline phase in the polishing layer as measured by pulse NMR at 80° C. is 2.6-3.1, and
a ratio (NC40/CC40) of a content proportion by weight (NC40) of the amorphous phase in the polishing layer as measured by pulse NMR at 40° C. to a content proportion by weight (CC40) of the crystalline phase in the polishing layer as measured at 40° C. is 0.5-0.9.
[19] A polishing pad having a polishing layer composed of a polyurethane resin foam derived from an isocyanate-terminated prepolymer and a curing agent,
in which the isocyanate-terminated prepolymer includes a polyisocyanate compound-derived configuration unit and a high-molecular-weight polyol-derived configuration unit,
the high-molecular-weight polyol-derived configuration unit is composed of at least a polypropylene glycol configuration unit and a polyester diol configuration unit, and
there is less than 60 weight % of the polypropylene glycol configuration unit with respect to the high-molecular-weight polyol-derived configuration unit.
[20] The polishing pad according to [19], in which there is 30-50 weight % of the polypropylene glycol configuration unit with respect to the high-molecular-weight polyol-derived configuration unit.
[21] The polishing pad according to [19] or [20], in which the polyester diol configuration unit is derived from a polyester diol having a number-average molecular weight of 600-2500.
[22] A method for manufacturing a polishing pad having a polishing layer composed of a polyurethane resin foam, the method including
a step of reacting a polyisocyanate compound and a high-molecular-weight polyol containing at least a polypropylene glycol and a polyester diol to obtain an isocyanate-terminated prepolymer,
a step of reacting the isocyanate-terminated prepolymer and a curing agent to obtain the polyurethane resin foam, and
a step of molding the polyurethane resin foam into a shape of the polishing layer,
in which there is less than 60 weight % of the polypropylene glycol with respect to a total amount of the high-molecular-weight polyol.

### Advantageous Effects of Invention

The polishing layer in the polishing pad of the present invention has a specific length of a distance between hard segments and is thereby capable of providing a polishing pad being excellent in terms of step elimination performance or defect performance and, furthermore, having excellent wear resistance.

### BRIEF DESCRIPTION OF DRAWINGS

FIG. 1 is a perspective view of a polishing device 1.

FIG. 2 is a cross-sectional view of a polishing pad.

FIG. 3 is the measurement results by small-angle X-ray scattering of respective polishing layers of polishing pads of Example 5 and Comparative Example 5.

FIG. 4 is an enlarged view of the vicinity of a surrounded portion in FIG. 3.

FIG. 5 is a view obtained by correcting the graph of FIG. 4 so as to facilitate the obtainment of the maximums.

FIG. 6 is a view showing pattern diagrams of a step state in a step polishing test.

FIG. 7 is a graph showing changes in the wear amounts (thicknesses) of polishing pads of an example and a comparative example.

FIG. 8 is the test results of the step elimination performance of an example and comparative examples.

FIG. 9 is the polishing test results of the defect performance of the example and the comparative examples.

### DESCRIPTION OF EMBODIMENTS

Hereinafter, an embodiment of an invention will be described, but the present invention is not limited to the embodiment of the invention.

### <<Polishing Pad>>

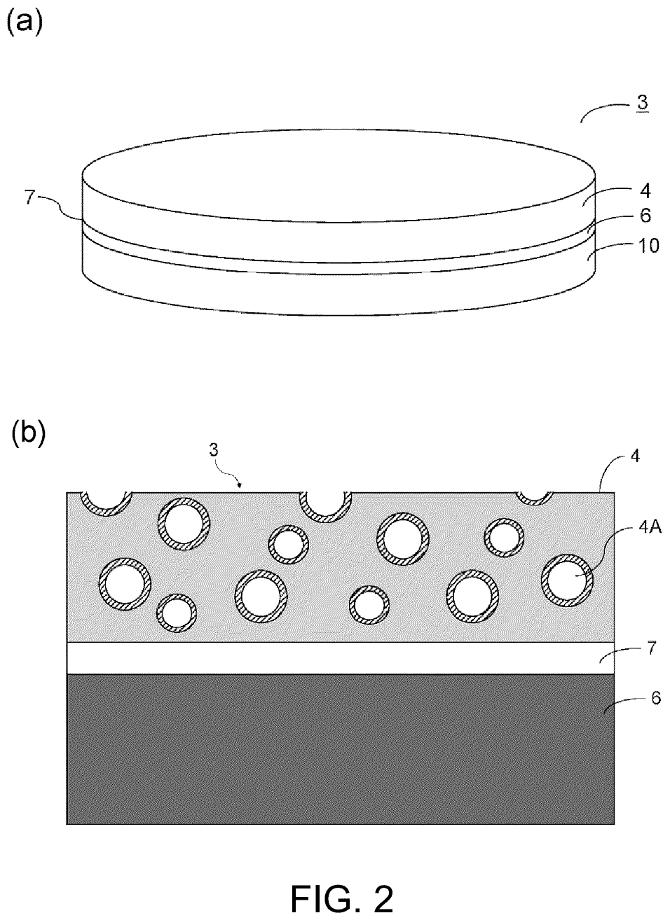

The structure of a polishing pad 3 will be described using FIG. 2(a). The polishing pad 3 includes a polishing layer 4 and a cushion layer 6 as shown in FIG. 2(a). The shape of the polishing pad 3 is preferably a disc shape, but is not particularly limited, and the size (diameter) can also be determined as appropriate depending on the size or the like of a polishing device 1 including the polishing pad 3 and can be set to, for example, approximately 10 cm to 2 m in diameter.

In the polishing pad 3 of the present invention, it is preferable that the polishing layer 4 adhere to the cushion layer 6 through an adhesive layer 7 as shown in FIG. 2(a).

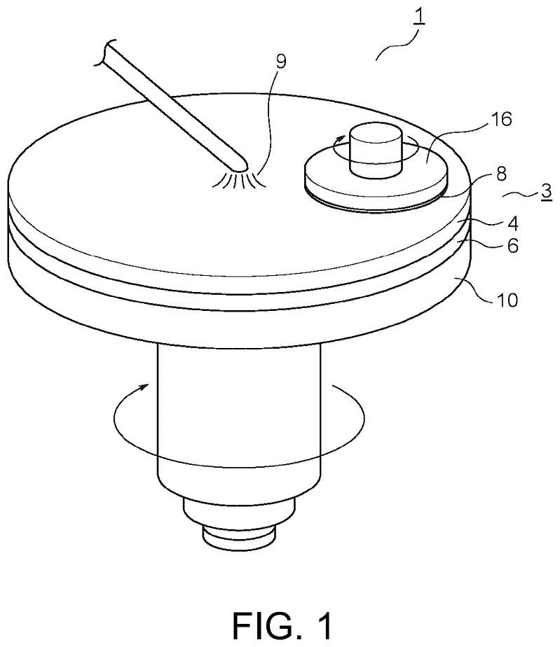

The polishing pad 3 is pasted to a polishing surface plate 10 of the polishing device 1 with double-sided tape or the like provided on the cushion layer 6. The polishing pad 3 is driven to rotate by the polishing device 1 in a state where the item to be polished 8 is pressed and polishes the item to be polished 8 (refer to FIG. 1).

### <Polishing Layer>

### (Configuration)

The polishing pad 3 includes the polishing layer 4 that is a layer for polishing the item to be polished 8. A material that configures the polishing layer 4 is a specific polyurethane resin.

The size (diameter) of the polishing layer 4 is the same as that of the polishing pad 3 and can be set to approximately 10 cm to 2 m in diameter, and the thickness of the polishing layer 4 can be set to normally approximately 1-5 mm.

The polishing layer 4 is rotated together with the polishing surface plate 10 of the polishing device 1 and polishes the item to be polished 8 by causing chemical components or abrasive grains that are contained in a slurry 9 to relatively move together with the item to be polished 8 while the slurry 9 is made to flow thereon.

The polishing layer 4 may include hollow microspheres 4A in a dispersed state. In a case where the hollow microspheres 4A are included in a dispersed state, once the polishing layer 4 is worn, the hollow microspheres 4A are exposed on a polishing surface, fine voids are generated on the polishing surface, and the slurry is held in these fine voids, whereby it is possible to further progress the polishing of the item to be polished 8.

The polishing layer 4 is formed by slicing a polyurethane resin foam obtained by casting and curing a liquid mixture in which an isocyanate-terminated prepolymer, a curing agent (chain extender) and, if necessary, the hollow microspheres 4A have been mixed together. That is, the polishing layer 4 has been dry-molded.

### (Distance Between Hard Segments)

In an aspect of the present invention, in the material that configures the polishing layer 4, the distance between hard segments as measured by small-angle X-ray scattering is 9.5 nm or less. When the distance between hard segments is 9.5 nm or less, the polishing pad including the polishing layer has excellent step elimination performance, excellent defect performance and excellent wear resistance.

The distance between hard segments is preferably 3.0-9.5 nm and more preferably 4.0-9.0 nm.

The distance between hard segments is measured by small-angle X-ray scattering. Here, the small-angle X-ray scattering is a method in which an X-ray is made incident on a sample and a scattered X-ray is obtained with a detector and enables the obtainment of data of the size, shape, structural correlation or the like of a measurement subject from the scattering angle in a non-destructive manner.

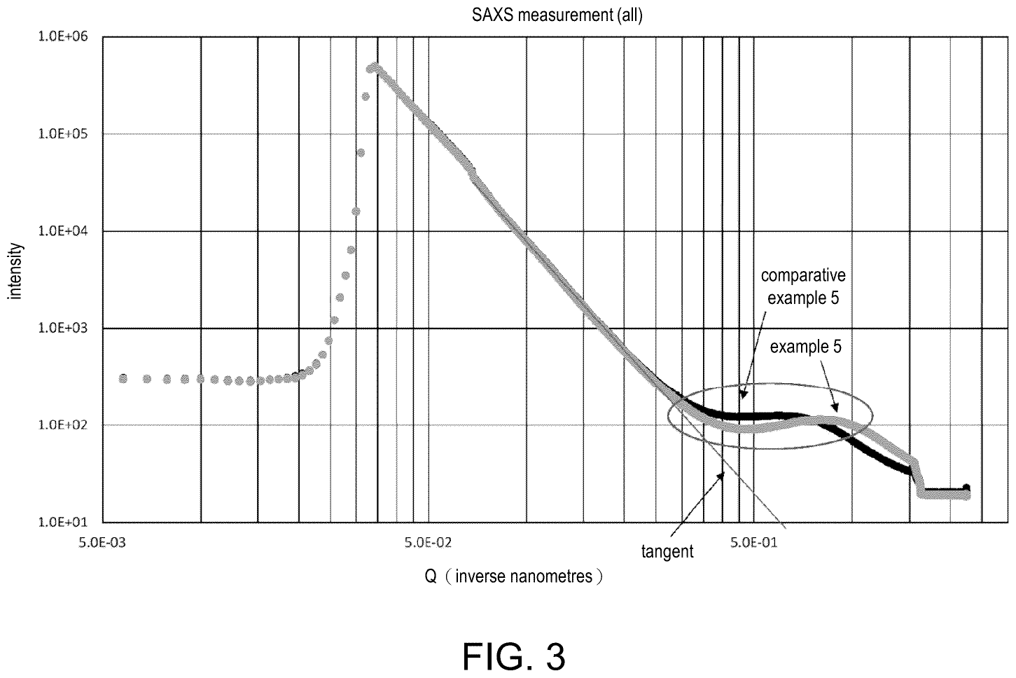

When the polishing layer 4 of the polyurethane resin foam is measured by small-angle X-ray scattering, a curve as shown in FIG. 3 can be obtained.

In the present specification, the hard segment means a part composed of a urethane bond or a urea bond that is formed by a reaction between an isocyanate in the polyurethane resin that configures the polishing layer 4 and a curing agent.

Ordinarily, in the case of being measured by small-angle X-ray scattering, the intensity of the obtained data is not used as it is, but the distance is studied with an intensity corrected using the following expression. Even in the present invention, the intensities have been corrected by this calculation.

Corrected intensity=(intensity of target sample/transmission of target sample)−(intensity of air/transmission of air)

The distance between hard segments is calculated from the value of Q at which the intensity is maximized in the surrounded portion in FIG. 3. That is, the distance between hard segments can be obtained from ‘distance=2π/Q’. Therefore, when the value of Q is small, the distance between hard segments becomes large.

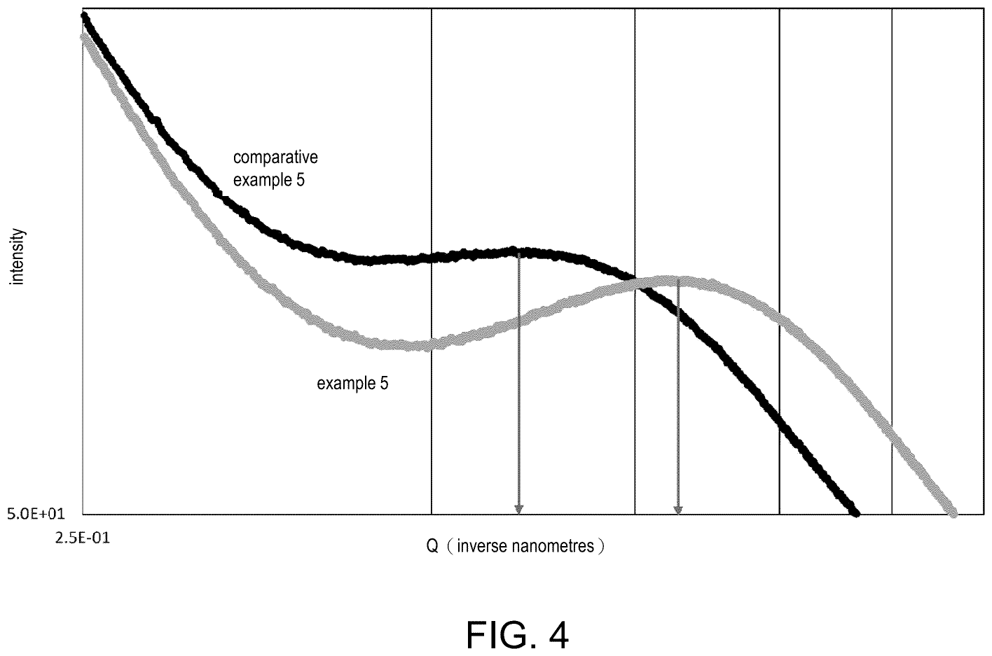

This will be described using FIG. 4. The curve of FIG. 4 is a curve corrected using transmission or the like. Attention is paid to a site with the highest peak in the flat portion of this FIG. 4, and the X axis corresponds to the distance between hard segments. When the distance between hard segments thus obtained is 9.5 nm or less, the polishing pad including the polishing layer has excellent step elimination performance, excellent defect performance and excellent wear resistance.

Furthermore, the curve is converted so as to facilitate the obtainment of the maximum. A graph is redrawn by the following method.

### (Redrawing Method)

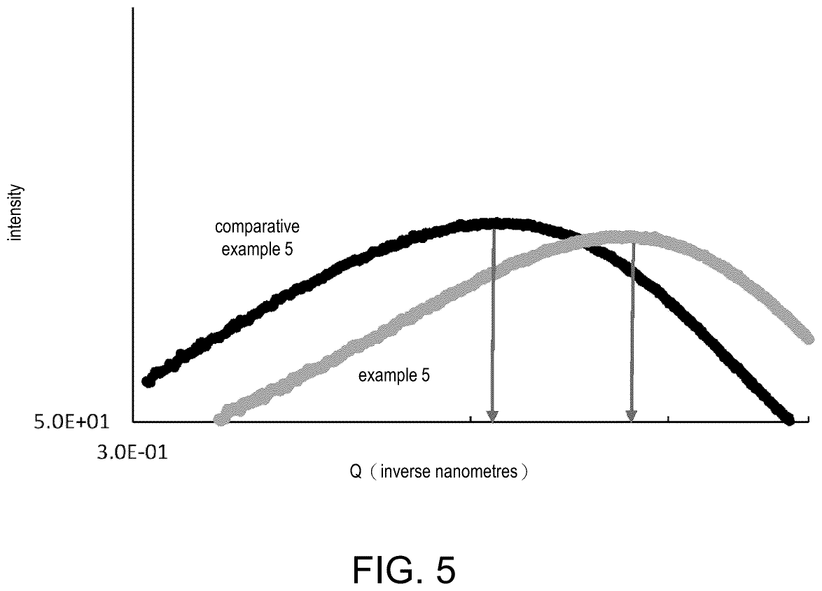

(1) A tangent is derived from, in the obtained curve, a portion where the intensity begins to decline. For example, in the measurement result of FIG. 3, a tangent is derived from an intensity for which Q is near 0.1-0.2.
(2) An intensity is obtained from the Q value (X) of the tangent derived in the (1), and a difference from a corrected intensity near the inflection point is calculated. For example, since the inflection point is present at Q of 0.3-1.2, an intensity obtained by assigning Q to an expression of the tangent is obtained from the measurement result of FIG. 3. After that, a difference is obtained by subtracting the intensity obtained by the expression of the tangent from the corrected intensity.
(3) A graph (normal distribution) of the intensity difference is created from the difference obtained in the (2).
(4) A peak (the peak of the graph shown in FIG. 5) in the normal distribution is assumed as the distance between hard segments.

In a case where the slope of the graph of the intensity difference is mild, there is a tendency that the sizes of hard segments are not uniform (a tendency that the sizes of hard segments are dispersed), and, in a case where the slope of the graph of the intensity difference is steep, there is a tendency that there are many hard segments with the same size (a tendency that the sizes of hard segments are similar).

As described already, when the distance between hard segments is 9.5 nm or less, favorable characteristics can be obtained, but this distance between hard segments can be adjusted by changing the material of the polishing layer 4 or changing the manufacturing method.

For example, in a case where both a polypropylene glycol and a polyester diol are used as the high-molecular-weight polyol, which is the material of the polishing layer 4, the distance between hard segments is changed by changing the proportions of the polypropylene glycol and the polyester diol. That is, it is possible it is possible to adjust the distance between hard segments by changing the proportions of the polypropylene glycol and the polyester diol.

### (Crystalline Phase, Intermediate Phase and Amorphous Phase)

As another aspect of the present invention, in the polishing layer 4 composed of the polyurethane resin foam, the ratio (NC80/CC80) of the content proportion by weight (NC80) of an amorphous phase in the polishing layer as measured by pulse NMR at 80° C. to the content proportion by weight (CC80) of a crystalline phase in the polishing layer as measured by pulse NMR at 80° C. is 2.6-3.1, and the ratio (NC40/CC40) of the content proportion by weight (NC40) of the amorphous phase in the polishing layer as measured by pulse NMR at 40° C. to the content proportion by weight (CC40) of the crystalline phase in the polishing layer as measured by pulse NMR at 40° C. is 0.5-0.9.

It is normal to perform polishing at approximately 40° C., but there are cases where the temperature of the polishing pad 3 increases to approximately 80° C. due to friction as polishing progresses. Therefore, the proportions of an amorphous phase and a crystalline phase at 80° C. are important. In a case where NC80/CC80 exceeds 3.1, since the proportion of the amorphous phase is larger than the proportion of the crystalline phase, there are cases where the wear resistance deteriorates, and, in a case where NC80/CC80 is less than 2.6, since the proportion of the amorphous phase is smaller than the proportion of the crystalline phase, there are cases where the step elimination performance or the defect performance deteriorates. The lower limit of NC80/CC80 is preferably 2.6 or more and more preferably 2.7 or more. The upper limit of NC80/CC80 is preferably 3.1 or less and more preferably 3.0 or less.

Furthermore, the proportions of the amorphous phase and the crystalline phase at 40° C. are also important. This is because, when the proportions of the amorphous phase and the crystalline phase at 40° C. are outside a specific range, the defect performance, the step elimination performance and the wear resistance deteriorate. In a case where the ratio (NC40/CC40) of the content proportion by weight (NC40) of the amorphous phase to the crystalline phase at 40° C. exceeds 0.9, since the proportion of the amorphous phase is too larger than the proportion of the crystalline phase, there are cases where the wear resistance deteriorates, and, in a case where NC40/CC40 is less than 0.5, since the proportion of the amorphous phase is too smaller than the proportion of the crystalline phase, there are cases where the step elimination performance or the defect performance deteriorates. The lower limit of NC40/CC40 is preferably 0.5 or more and more preferably 0.6 or more. The upper limit of NC40/CC40 is preferably 0.9 or less and more preferably 0.8 or less.

Furthermore, in the polishing layer 4, the numerical value that is obtained from Expression (1) below is preferably larger than 1.9 and smaller than 2.2.

[Expression 2]

(NC80/CC80)−(NC40/CC40) (1)

Expression (1) means the balance between the amorphous phase and the crystalline phase with respect to the temperature change of the polishing pad during polishing. In a case where this value is 1.9 or less, there are cases where the step elimination performance or the defect performance deteriorates, and, when the value is 2.2 or more, there are cases where the wear resistance deteriorates.

The lower limit of the value that is obtained from Expression (1) is preferably 1.95 or more and more preferably 2.00 or more. The upper limit of the value that is obtained from Expression (1) is preferably 2.15 or less and more preferably 2.10 or less.

Furthermore, the proportion of the amorphous phase (NC40) at 40° C. in the polishing layer 4 is preferably 22.0-27.0 weight % with respect to the weight of the entire polishing layer. When NC40 is 22.0-27.0 weight %, since soft segments has a certain amount of the amorphous phase, excellent step elimination performance and wear resistance are exhibited.

The crystalline phase (CC80) at 80° C. in the polishing layer 4 is preferably 19.0-22.0 weight %. When CC80 is 19.0-22.0 weight %, the polishing pad has appropriate hardness, and the defect performance or the step elimination performance improves, which is preferable.

In addition, in the present invention, the proportions of the crystalline phase, an intermediate phase and the amorphous phase in the polishing layer 4 can be obtained by measurement by pulse NMR. In pulse NMR measurement, the polyurethane resin foam is divided into three components of a short phase (S phase), a middle phase (M phase) and a long phase (L phase) in an ascending order of the spin-spin relaxation time, and the content proportion by weight of each phase is obtained. Regarding the content proportions of the S phase, the M phase and the L phase, for example, in the pulse NMR measurement, mainly the crystalline phase is observed as the S phase, mainly the amorphous phase is observed as the L phase, and mainly the intermediate phase is observed as the M phase. In addition, in the pulse NMR measurement, mainly the hard segment is observed as the S phase, and mainly the soft segment is observed as the L phase in the pulse NMR measurement.

The spin-spin relaxation time can be obtained by performing measurement by the solid echo method using, for example, “JNM-MU25” manufactured by JEOL, Ltd.

### (Hollow Microspheres)

The hollow microspheres 4A that may be included in the polishing layer 4 in the polishing pad of the present invention can be confirmed as hollow bodies on the polishing surface of the polishing layer 4 or a cross-section of the polishing layer 4, and the hollow bodies normally have opening diameters (diameters of the hollow microspheres 4) of 2-200 μm. The average bubble diameter is preferably 5 μm or more and less than 20 μm. Examples of the shape of the hollow microsphere 4A include a spherical shape, an elliptical shape and shapes close thereto.

As the hollow microspheres 4A, commercially available balloons can be used, and examples thereof include already-expanded balloons and unexpanded balloons. The unexpanded balloons are thermal expandable microspheres and can be thermally expanded in the manufacturing process to be bubbles having a predetermined size. In the present invention, commercially available balloons can be appropriately used as necessary.

### (Grooving)

On the surface of the polishing layer 4 of the present invention on the item to be polished 8 side, it is possible to provide grooving. Grooves are not particularly limited and may be any of slurry discharge grooves that communicate with the circumference of the polishing layer 4 and slurry holding grooves that do not communicate with the circumference of the polishing layer 4, and both the slurry discharge grooves and the slurry holding grooves may be provided. Examples of the slurry discharge grooves include lattice grooves, radial grooves and the like, examples of the slurry holding grooves include concentric circular grooves, perforations (through-holes) and the like, and it is also possible to combine these.

### <Cushion Layer>

### (Configuration)

The polishing pad 3 of the present invention has the cushion layer 6. It is desirable that the cushion layer 6 make the contact of the polishing layer 4 with the item to be polished 8 more uniform. As a material of the cushion layer 6, the cushion layer may be composed of any of a flexible material such as an impregnated non-woven fabric impregnated with a resin, a synthetic resin or rubber, a foam having a bubble structure or the like. Examples thereof include resins such as polyurethane, polyethylene, polybutadiene and silicone, rubber such as natural rubber, nitrile rubber and polyurethane rubber, and the like. From the viewpoint of adjusting the density and the compressive elastic modulus, an impregnated non-woven fabric is preferable, and polyurethane is preferably used as a resin material that is used to impregnate the non-woven fabric.

In addition, as the cushion layer 6, a sponge-like polyurethane resin layer having microscopic bubbles is also preferably used.

The compressive elastic modulus, density and bubbles of the cushion layer 6 in the polishing pad 3 of the present invention are not particularly limited, and a cushion layer 6 having well-known characteristic values can be used.

### <Adhesive Layer>

The adhesive layer 7 is a layer for making the cushion layer 6 and the polishing layer 4 adhere to each other and is normally composed of double-sided tape or an adhesive. As the double-sided tape or adhesive, it is possible to use double-sided tape or an adhesive (for example, adhesive sheet) that is well-known in the related art.

The polishing layer 4 and the cushion layer 6 are pasted to each other with the adhesive layer 7. The adhesive layer 7 can be formed of at least one pressure-sensitive adhesive selected from an acrylic pressure-sensitive adhesive, an epoxy-based pressure-sensitive adhesive and a urethane-based pressure-sensitive adhesive. For example, it is possible to use an acrylic pressure-sensitive adhesive and to set the thickness to 0.1 mm.

The polishing pad 3 of the present invention is excellent in terms of step elimination performance or defect performance and, furthermore, has excellent wear resistance.

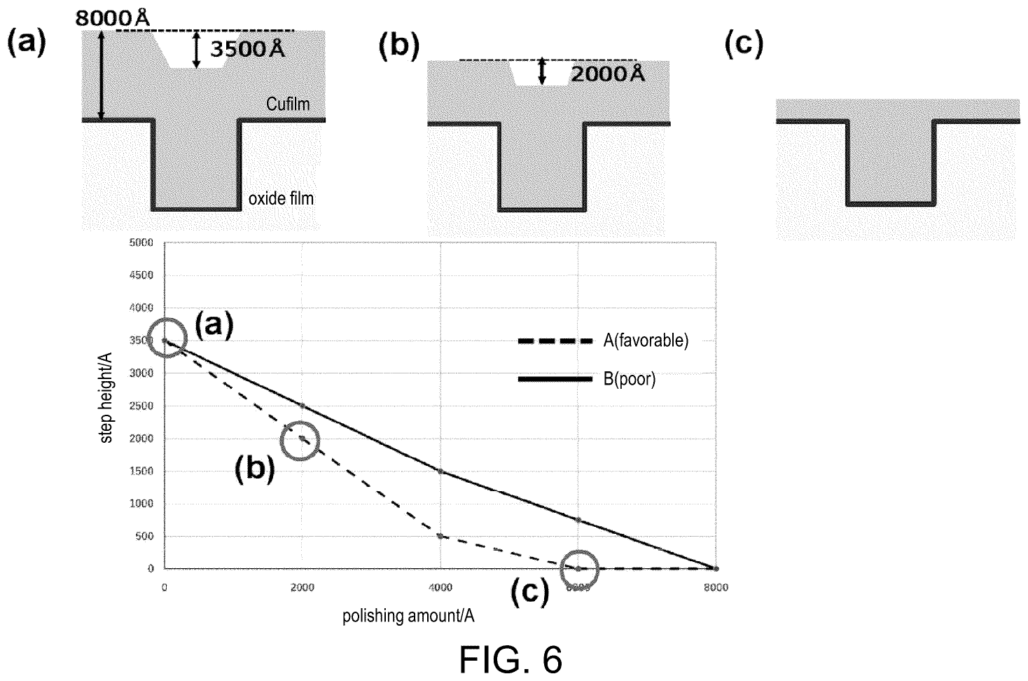

Here, the step elimination performance refers to performance of decreasing the number of steps (unevenness) in patterned wafers having the steps as polishing progresses. Pattern diagrams of a test for measuring the step elimination performance are shown in FIG. 6. Step elimination states in the case of using a polishing pad having high step elimination performance (dotted line) and in the case of using a polishing pad having relatively low step elimination performance (solid line) in a case where there are 3500-angstrom steps in an item to be polished are shown. While there is no difference at a point in time of (a) in FIG. 6, as polishing progresses, when the polishing amount reaches 2000 angstroms, it is shown that the number of the steps is small for the polishing pad having high step elimination performance (dotted line) compared with the polishing pad having relatively low step elimination performance (solid line) ((b)), and, with the polishing pad having high step elimination performance, the steps are eliminated relatively fast ((c)). The polishing pad indicated by the dotted line can be said to have relatively high step elimination performance than the polishing pad indicated by the solid line.

In addition, “defect” means a collective term for defects including “particle” indicating a remaining fine particle attached to the surface of an item to be polished, “pad debris” indicating debris of a polishing layer attached to the surface of the item to be polished, and “scratch” indicating a mark formed on the surface of the item to be polished, and defect performance refers to performance of decreasing the number of this “defect”.

In addition, wear resistance refers to resistance to wear.

### <<Method for Manufacturing Polishing Pad>>

A method for manufacturing the polishing pad 3 of the present invention will be described.

### <Material of Polishing Layer>

As a material of the polishing layer, in the present invention, a main component is a polyurethane resin. Examples of a specific main component include polyurethane resin foam materials that are obtained by reacting an isocyanate-terminated prepolymer and a curing agent.

Examples of a method for manufacturing the polishing layer 4 using an isocyanate-terminated prepolymer and a curing agent include methods including a preparation step of preparing the isocyanate-terminated prepolymer; a material preparation step of preparing the isocyanate-terminated prepolymer, the curing agent, an arbitrarily selective additive and arbitrarily selective hollow microspheres; a mixing step of mixing the isocyanate-terminated prepolymer, the curing agent, the arbitrarily selective additive and the arbitrarily selective hollow microspheres to obtain a liquid mixture for molding a compact; and a curing step of molding a polishing layer from the liquid mixture for molding a compact.

Hereinafter, the preparation step; the material preparation step, the mixing step and the molding step will be each described.

### <Preparation Step>

The isocyanate-terminated prepolymer that is used in the present invention can be obtained by reacting a polyisocyanate compound and a high-molecular-weight polyol such as a polypropylene glycol or a polyester diol and includes an isocyanate group at the molecular end. As the isocyanate-terminated prepolymer, a commercially available isocyanate-terminated prepolymer can be used if there is any, and it is normal to use an isocyanate-terminated prepolymer obtained by partially reacting a polyisocyanate compound and a polyol compound as the prepolymer. The reaction is not particularly limited, and an addition polymerization reaction may be performed using a method and conditions that are well-known in the manufacturing of polyurethane resins. For example, the urethane bond-containing polyisocyanate compound can be manufactured by a method in which a polyisocyanate compound heated to 50° C. is added to a polyol compound heated to 40° C. in a nitrogen atmosphere under stirring, after 30 minutes, the mixture is heated up to 80° C. and further reacted at 80° C. for 60 minutes.

The NCO equivalent of the isocyanate-terminated prepolymer is not particularly limited, but is preferably 500-600. This is because, when the NCO equivalent is less than 500, there are cases where the defect performance deteriorates, and, when the NCO equivalent exceeds 600, a desired polishing rate cannot be obtained, and there are cases where the step elimination performance deteriorates.

Hereinafter, each component will be described.

### (Polyisocyanate Compound)

For the isocyanate-terminated prepolymer, a polyisocyanate compound is used as a raw material.

As the polyisocyanate compound, a commercially available polyisocyanate compound may be used and there are no particular limitations.

In the present specification, the polyisocyanate compound means a compound having two or more isocyanate groups in the molecule.

The polyisocyanate compound is not particularly limited as long as two or more isocyanate groups are present in the molecule. Examples of a diisocyanate compound having two isocyanate groups in the molecule include m-phenylene diisocyanate, p-phenylene diisocyanate, 2,6-tolylene diisocyanate (2,6-TDI), 2,4-tolylene diisocyanate (2,4-TDI), naphthalene-1,4-diisocyanate, diphenylmethane-4,4′-diisocyanate (MDI), 4,4′-methylene-bis(cyclohexyl isocyanate) (hydrogenated MDI), 3,3′-dimethoxy-4,4′-biphenyl diisocyanate, 3,3′-dimethyldiphenylmethane-4,4′-diisocyanate, xylylene-1,4-diisocyanate, 4,4′-diphenylpropane diisocyanate, trimethylene diisocyanate, hexamethylene diisocyanate, propylene-1,2-diisocyanate, butylene-1,2-diisocyanate, cyclohexylene-1,2-diisocyanate, cyclohexylene-1,4-diisocyanate, p-phenylene diisothiocyanate, xylylene-1,4-diisothiocyanate, ethylidine diisothiocyanate and the like. These polyisocyanate compounds may be used singly or a plurality of polyisocyanate compounds may be used in combination.

As the polyisocyanate compound, 2,4-TDI and/or 2,6-TDI is preferably contained.

### (High-Molecular-Weight Polyol as Raw Material of Isocyanate-Terminated Prepolymer)

In the present specification, “polyol” means a compound having two or more hydroxyl groups (OH) in the molecule. In addition, “high molecular weight” refers to a molecular weight of 500 or more.

In the present invention, examples of the high-molecular-weight polyol as a raw material of the isocyanate-terminated prepolymer include diol compounds such as ethylene glycol, diethylene glycol (DEG) and butylene glycol, triol compounds and the like; polyether polyol compounds such as poly(oxytetramethylene) glycol (or polytetramethylene ether glycol) (PTMG); polyester diols.

Among these, it is preferable to use a polypropylene glycol and a polyester diol in combination from the viewpoint of being capable of adjusting the distance between hard segments and the viewpoint of easily adjusting the proportions of the crystalline phase and the amorphous phase. Hereinafter, the polypropylene glycol and the polyester will be described.

The polypropylene glycol that can be used in the present invention is not particularly limited, and examples thereof include polypropylene glycols having a number-average molecular weight (Mn) of 500-2000, more preferably 650-1000.

The number-average molecular weight can be measured by gel permeation chromatography (GPC). In the case of measuring the number-average molecular weight of the polyol compound from the polyurethane resin, it is also possible to estimate the number-average molecular weight by GPC after each component is decomposed by a normal method such as amine decomposition.

In the present invention, as the high-molecular-weight polyol as a raw material of the isocyanate-terminated prepolymer, a polyester diol can be used. In the present specification, the polyester diol has two or more ester bonds and two hydroxyl groups (OH).

The polyester diol can be obtained by, for example, reacting a dicarboxylic acid compound and a diol compound.

Examples of the dicarboxylic acid compound include aliphatic dicarboxylic acids such as succinic acid, glutaric acid, adipic acid, pimelic acid, suberic acid, azelaic acid, sebacic acid, decanedioic acid and dodecanedioic acid; unsaturated bond-containing dicarboxylic acids such as maleic anhydride, maleic acid and fumaric acid; alicyclic polycarboxylic acids such as 1,3-cyclopentanedicarboxylic acid and 1,4-cyclohexanedicarboxylic acid; aromatic dicarboxylic acids such as phthalic acid, terephthalic acid, isophthalic acid, 1,4-naphthalenedicarboxylic acid, 2,5-naphthalenedicarboxylic acid, 2,6-naphthalenedicarboxylic acid, naphthalic acid, biphenyldicarboxylic acid, diphenic acid and anhydrides thereof; and the like, and these dicarboxylic acid compounds can be used singly or in combination.

Examples of the diol compound that is used to synthesize the polyester diol include ethylene glycol, diethylene glycol, triethylene glycol, 1,2-propanediol, 1,3-propanediol, 2-methyl 1,3-propanediol, 1,3-butanediol, 1,4-butanediol, neopentyl glycol, 1,5-pentanediol, 3-methyl-1,5-pentanediol, 1,6-hexanediol and the like, and these diol compounds can be used singly or in combination.

Among them, a polyester diol of adipic acid and 1,4-butanediol and a polyester diol of adipic acid and diethylene glycol are preferable.

The number-average molecular weight of the polyester diol is preferably 600-2500 from the viewpoint of exhibiting rubber elasticity necessary for the polishing pad as the soft segment.

There is preferably less than 60 weight % of the polypropylene glycol with respect to the entire high-molecular-weight polyol. In the case of 60 weight % or more, there are cases where the wear resistance deteriorates. There is preferably 30-50 weight % of the polypropylene glycol with respect to the entire high-molecular-weight polyol.

In addition, there is preferably 70 weight % or less of the polyester diol with respect to the entire high-molecular-weight polyol. When there is more than 70 weight % of the polyester diol, there are cases where the step elimination performance deteriorates. There is preferably 50-70 weight % of the polyester diol with respect to the entire high-molecular-weight polyol. The total amount of the polypropylene glycol and the polyester diol is preferably 80 weight % or more with respect to the entire high-molecular-weight polyol. This is because, when the total amount is 80 weight % or more, the effect is significantly exhibited.

In the present invention, as the high-molecular-weight polyol, polyoxytetramethylene glycol or the like may also be used, and there is preferably 10 weight % or less of the polyoxytetramethylene glycol or the like, more preferably 5 weight % or less and still more preferably 3 weight % or less with respect to the entire high-molecular-weight polyol. When there is more than 10 weight % of the polyoxytetramethylene glycol or the like, there are cases where the step elimination performance or the defect performance becomes insufficient.

### <Material Preparation Step>

In order to manufacture the polishing layer 4 of the present invention, the isocyanate-terminated prepolymer, a curing agent, an arbitrarily selective additive and arbitrarily selective hollow microspheres are prepared. Since the isocyanate-terminated prepolymer has been already described, here, the curing agent, the additive and the hollow microspheres will be described.

### (Curing Agent)

In the method for manufacturing the polishing layer 4 of the present invention, a curing agent (also referred to as a chain extender) is mixed with the isocyanate-terminated prepolymer or the like in the mixing step. When the curing agent is added, in a subsequent compact molding step, it is possible for a main chain end of the urethane bond-containing polyisocyanate compound to bond to the curing agent to form a polymer chain and for the urethane bond-containing polyisocyanate compound to cure.

Examples of the curing agent include polyvalent amine compounds such as ethylenediamine, propylenediamine, hexamethylenediamine, isophoronediamine, dicyclohexylmethane-4,4′-diamine, 3,3′-dichloro-4,4′-diaminodiphenylmethane (MOCA), 4-methyl-2,6-bis(methylthio)-1,3-benzenediamine, 2-methyl-4,6-bis(methylthio)-1,3-benzenediamine, 2,2-bis(3-amino-4-hydroxyphenyl)propane, 2,2-bis[3-(isopropylamino)-4-hydroxyphenyl]propane, 2,2-bis[3-(1-methylpropylamino)-4-hydroxyphenyl]propane, 2,2-bis[3-(1-methylpentylamino)-4-hydroxyphenyl]propane, 2,2-bis(3,5-diamino-4-hydroxyphenyl)propane, 2,6-diamino-4-methylphenol, trimethylethylene bis-4-aminobenzonate and polytetramethylene oxide-di-p-aminobenzonate; and polyvalent alcohol compounds such as ethylene glycol, propylene glycol, diethylene glycol, trimethylene glycol, tetraethylene glycol, triethylene glycol, dipropylene glycol, 1,4-butanediol, 1,3-butanediol, 2,3-butanediol, 1,2-butanediol, 3-methyl-1,2-butanediol, 1,2-pentanediol, 1,4-pentanediol, 2,4-pentanediol, 2,3-dimethyltrimethylene glycol, tetramethylene glycol, 3-methyl-4,3-pentanediol, 3-methyl-4,5-pentanediol, 2,2,4-trimethyl-1,3-pentanediol, 1,6-hexanediol, 1,5-hexanediol, 1,4-hexanediol, 2,5-hexanediol, 1,4-cyclohexanedimethanol, neopentyl glycol, glycerin, trimethylolpropane, trimethylolethane, trimethylolmethane, poly(oxytetramethylene) glycol, polyethylene glycol and polypropylene glycol. In addition, the polyvalent amine compounds may have a hydroxyl group, and examples of such amine-based compound include 2-hydroxyethylethylenediamine, 2-hydroxyethylpropylenediamine, di-2-hydroxyethylethylenediamine, di-2-hydroxyethylpropylenediamine, 2-hydroxypropylethylenediamine, di-2-hydroxypropylethylenediamine and the like. As the polyvalent amine compounds, diamine compounds are preferable, and, for example, 3,3′-dichloro-4,4′-diaminodiphenylmethane (methylenebis-o-chloroaniline) (hereinafter, abbreviated as MOCA) is more preferably used.

### (Additive)

As the material of the polishing layer 4, an additive, such as an oxidant, can be added as necessary. In the present invention, the additive is not particularly limited as long as the additive does not impair the effect of the present invention.

### (Hollow Microspheres)

The polishing layer 4 includes the hollow microspheres 4A each having an outer shell and being hollow inside as necessary. As described above, as a material of the hollow microspheres 4A, commercially available hollow microspheres can be used. Alternatively, hollow microspheres synthesized by a normal method and thus obtained may also be used. A material of the outer shell of the hollow microsphere 4A is not particularly limited, and examples thereof include polyvinyl alcohol, polyvinylpyrrolidone, poly(meth)acrylic acid, polyacrylamide, polyethylene glycol, polyhydroxy ether acrylate, maleic acid copolymers, polyethylene oxide, polyurethane, poly(meth)acrylonitrile, polyvinylidene chloride, polyvinyl chloride, organic silicone-based resins and copolymers obtained by combining two or more monomers that configure these resins. In addition, commercially available hollow microspheres are not limited to the followings, but examples thereof include EXPANCEL series (trade name manufactured by Akzo Nobel N.V.), MATSUMOTO MICROSPHERE (trade name manufactured by Matsumoto Yushi-Seiyaku Co., Ltd.) and the like.

The amount of the material of the hollow microspheres 4A added is preferably 0.1-10 parts by mass, more preferably 1-5 parts by mass and still more preferably 1-3 parts by mass with respect to 100 parts by mass of the isocyanate-terminated prepolymer.

In addition, apart from the above-described components, a blowing agent that has been conventionally used may be jointly used with the hollow microspheres 4A to an extent that the effect of the present invention is not impaired, and a non-reactive gas may be blown to each of the components in the mixing step. Examples of the blowing agent include, apart from water, blowing agents containing hydrocarbon having 5 or 6 carbon atoms as a main component. Examples of the hydrocarbon include chain hydrocarbons such as n-pentane and n-hexane and alicyclic hydrocarbons such as cyclopentane and cyclohexane.

As a method for manufacturing the prepolymer, for example, the polyisocyanate compound, the polypropylene glycol and the polyester diol may be mixed and reacted or a mixture 1 of the polyisocyanate compound and the polypropylene glycol and a mixture 2 of the polyisocyanate compound and the polyester diol may be mixed and thereby reacted.

### <Mixing Step>

In the mixing step, the isocyanate-terminated prepolymer, the curing agent, the arbitrarily selective additive and the arbitrarily selective hollow microspheres obtained in the preparation step are supplied to a mixer and stirred and mixed together. The mixing step is performed in a state where the components have been heated to a temperature where the fluidity of each of the components can be secured; however, when the components are heated too much, the hollow microspheres expand and do not have a predetermined opening distribution, and thus caution needs to be taken.

### <Molding Step>

In the compact molding step, a liquid mixture for molding a compact prepared in the mixing step is made to flow into a formwork preheated to 30-100° C. and primarily cured, then, heated at approximately 100-150° C. for approximately 10 minutes to five hours to be secondarily cured, thereby molding a cured polyurethane resin (polyurethane resin compact). At this time, the isocyanate-terminated prepolymer and the curing agent react with each other to form a polyurethane resin foam, whereby the liquid mixture cures.

When the viscosity is too high, the fluidity becomes poor, and it becomes difficult to mix the isocyanate-terminated prepolymer substantially uniformly during mixing. When the viscosity is decreased by increasing the temperature, the pot life becomes short, conversely, mixed stains are generated, and a variation is caused in the sizes of hollow microspheres that are included in a foam to be obtained. Particularly, when the reaction temperature is too high, in a case where the unexpanded hollow microspheres are used, the hollow microspheres expand more than necessary, and it becomes impossible to obtain desired pores. On the contrary, when the viscosity is too low, bubbles move in the liquid mixture, and it becomes difficult to obtain a foam where the hollow microspheres have substantially evenly dispersed. Therefore, the viscosity of the isocyanate-terminated prepolymer is preferably set within a range of 500-4000 mPa-s at a temperature of 50-80° C. Regarding this, the viscosity can be set by, for example, changing the molecular weight (degree of polymerization) of the isocyanate-terminated prepolymer. The isocyanate-terminated prepolymer is heated to approximately 50-80° C. and put into a flowable state.

In the molding step, the liquid mixture cast as necessary is reacted in the framework to form a foam. At this time, the isocyanate-terminated prepolymer crosslink-cures by the reaction between the isocyanate-terminated prepolymer and the curing agent.

After a compact is obtained, the compact is sliced in a sheet shape to form a plurality of polishing layers 4. For the slicing, an ordinary slicing machine can be used. During the slicing, the compact is sequentially sliced from the upper layer part to a predetermined thickness while the lower layer part of the polishing layer 4 is held. The thickness to be sliced is set, for example, within a range of 1.3-2.5 mm. In a foam molded with a 50 mm-thick framework, for example, approximately 10 mm parts in the upper layer part and the lower layer part of the foam cannot be used due to scratches or the like, and 10-25 polishing layers 4 are formed from the approximately 30 mm central part. A foam in which the hollow microspheres 4A have been substantially evenly formed is obtained in the curing molding step.

Grooving may be performed on a polishing surface of the obtained polishing layer 4 as necessary. In the present invention, a method for the grooving and the groove shape are not particularly limited.

In the polishing layer 4 thus obtained, after that, double-sided tape is pasted to a surface opposite to the polishing surface of the polishing layer 4. The double-sided tape is not particularly limited, and double-sided tape can be arbitrarily selected from double-sided tapes that are well-known in the related art and used.

### <Method for Manufacturing Cushion Layer 6>

The cushion layer 6 is preferably composed of an impregnated non-woven fabric impregnated with a resin. Preferable examples of the resin that is used to impregnate the non-woven fabric include polyurethanes such as polyurethane and polyurethane polyurea, acrylics such as polyacrylate and polyacrylonitrile, vinyls such as polyvinyl chloride, polyvinyl acetate and polyvinylidene fluoride, polysulfones such as polysulfone and polyethersulfone, acylated celluloses such as acetylated cellulose and butyrylated cellulose, polyamides, polystyrenes and the like. The density of the non-woven fabric before being impregnated with the resin (in a web state) is preferably 0.3 g/cm³ or less and more preferably 0.1-0.2 g/cm³. In addition, the density of the non-woven fabric after being impregnated with the resin is preferably 0.7 g/cm³ or less and more preferably 0.25-0.5 g/cm³. When the densities of the non-woven fabric before being impregnated with the resin and after being impregnated with the resin are the above-described upper limits or less, the processing accuracy improves. In addition, when the densities of the non-woven fabric before being impregnated with the resin and after being impregnated with the resin are the above-described lower limits or more, it is possible to reduce the permeation of the polishing slurry into a base material layer. The rate of the resin attached to the non-woven fabric is represented by the weight of the resin attached with respect to the weight of the non-woven fabric and is preferably 50 weight % or more and more preferably 75-200 weight %. When the rate of the resin attached to the non-woven fabric is the above-described upper limit or less, it is possible for the cushion layer to have desired cushioning properties.

### <Joining Step>

In a joining step, the formed polishing layer 4 and cushion layer 6 are pasted (joined) to each other with the adhesive layer 7. As the adhesive layer 7, for example, an acrylic pressure-sensitive adhesive is used, and the adhesive layer 7 is formed so as to be 0.1 mm in thickness. That is, the acrylic pressure-sensitive adhesive is applied onto the surface of the polishing layer 4 opposite to the polishing surface in a substantially uniform thickness. The surface of the polishing layer 4 opposite to the polishing surface and the surface of the cushion layer 6 are pressed against each other across the applied pressure-sensitive adhesive, thereby pasting the polishing layer 4 and the cushion layer 6 to each other with the adhesive layer 7. In addition, the laminate is cut into a desired shape such as a circular shape, an inspection is performed to confirm whether or not dirt, foreign matters or the like are attached, and the polishing pad 3 is completed.

### EXAMPLES

Hereinafter, the present invention will be described in more detail with examples, but the present invention is not limited to these examples.

In each of the examples and comparative examples, “parts” means “parts by mass” unless particularly otherwise described.

In addition, an NCO equivalent is a numerical value indicating the molecular weight of a prepolymer (PP) per NCO group that is obtained by “(the mass (parts) of a polyisocyanate compound+the mass (parts) of a polyol compound)/[(the number of functional groups per molecule of the polyisocyanate compound×the mass (parts) of the polyisocyanate compound/the molecular weight of the polyisocyanate compound)−(the number of functional groups per molecule of the polyol compound×the mass (parts) of the polyol compound/the molecular weight of the polyol compound)].”

### Embodiment 1

### (Manufacturing of Polishing Layer)

3 Parts of already-expanded hollow microspheres each having a shell part composed of an acrylonitrile-vinylidene chloride copolymer and containing an isobutane gas in the shell were added to and mixed with 100 parts of an isocyanate-terminated urethane prepolymer having an NCO equivalent of 520 that had been formed by reacting 2,4-tolylene diisocyanate (TDI) and a high-molecular-weight polyol shown in Table 1, thereby obtaining a liquid mixture. The obtained liquid mixture was charged into a first liquid tank and kept warm. Next, separately from a first liquid, 23.1 parts of MOCA was charged into a second liquid tank as a curing agent and kept warm in the second liquid tank. The respective liquids in the first liquid tank and the second liquid tank were injected into a mixer equipped with two inlets such that an R value, which indicates the equivalence ratio at each inlet of an amino group and a hydroxyl group present in the curing agent with respect to a terminal isocyanate group in the prepolymer, reached 0.90. The two injected liquids were injected into a mold of a molding machine preheated to 80° C. while being mixed and stirred, then, the mold was clamped, and a molding was heated for 30 minutes and primarily cured. The primarily-cured molding was released from the mold and then secondarily cured in an oven at 120° C. for four hours, thereby obtaining a urethane molding. The obtained urethane molding was naturally cooled to 25° C., then, heated again in the oven at 120° C. for five hours and then sliced in a thickness of 1.3 mm, thereby obtaining a polishing layer corresponding to each of the examples and the comparative examples.

### <Manufacturing of Cushion Layer>

A non-woven fabric composed of polyester fibers was immersed in a urethane resin solution (manufactured by DIC Corporation, trade name “C1367”). After the immersion, the resin solution was squeezed using a mangle roller capable of pressurization between a pair of rollers to substantially uniformly impregnate the non-woven fabric with the resin solution. Next, the non-woven fabric was immersed in a coagulating liquid composed of water of room temperature to coagulate and regenerate the impregnating resin, thereby obtaining a resin-impregnated non-woven fabric. After that, the resin-impregnated non-woven fabric was removed from the coagulating liquid, furthermore, immersed in a washing liquid composed of water to remove N,N-dimethylformamide (DMF) in the resin and then dried. After the drying, a skin layer on the surface was removed by a buffing treatment to produce a 1.3 mm-thick cushion layer.

### Examples and Comparative Examples

Each polishing layer formed of components shown in Table 1 and the cushion layer were joined with 0.1 mm-thick double-sided tape (tape including adhesives composed of an acrylic resin on both surfaces of a PET base material), thereby manufacturing a polishing pad of each of Examples 1-4 and Comparative Examples 1-3. In addition, a polishing pad IC1000 (manufactured by NITTA DuPont Incorporated), which was conventionally well known, was used as Comparative Example 4.

In addition, ester A indicates a polyester diol having a number-average molecular weight of 1000 obtained by reacting adipic acid and diethylene glycol, ester B indicates a polyester diol having a number-average molecular weight of 1000 obtained by reacting adipic acid and butanediol, and PPG indicates a polypropylene glycol having a number-average molecular weight of 1000, respectively.

TABLE 1

| | Prepolymer | | | | | | |
|---|---|---|---|---|---|---|---|
| | | PPG | | | | | D |
| | High-molecular-weight | compounding | NCO | Curing | R | Density | hardness |
| | polyol weight ratio | ratio | equivalent | agent | value | (g/cm³) | (°) |
| Example 1 | PPG:ester A = 5:5 | 50 | 520 | MOCA | 0.90 | 0.84 | 46.0 |
| Example 2 | PPG:ester A = 3:7 | 30 | | | | 0.86 | 47.0 |
| Example 3 | PPG:ester B = 5:5 | 50 | | | | 0.82 | 46.5 |
| Example 4 | PPG:ester B = 3:7 | 30 | | | | 0.80 | 45.5 |
| Comparative | PPG:100% | 100 | | | | 0.84 | 49.5 |
| Example 1 | | | | | | | |
| Comparative | PPG:ester A = 7:3 | 70 | | | | 0.86 | 47.0 |
| Example 2 | | | | | | | |
| Comparative | PPG:ester B = 7:3 | 70 | | | | 0.83 | 43.5 |
| Example 3 | | | | | | | |

### (Density)

The densities (g/cm³) of the polishing layers were measured according to Japanese Industrial Standards (JIS K 6505).

### (D Hardness)

The D hardness of the polishing layers was measured using a D-type hardness meter according to Japanese Industrial Standards (JIS-K-6253). Here, a measurement sample was obtained by overlaying a plurality of the polishing layers as necessary so that the total thickness reached at least 4.5 mm or greater.

### (Wear Test)

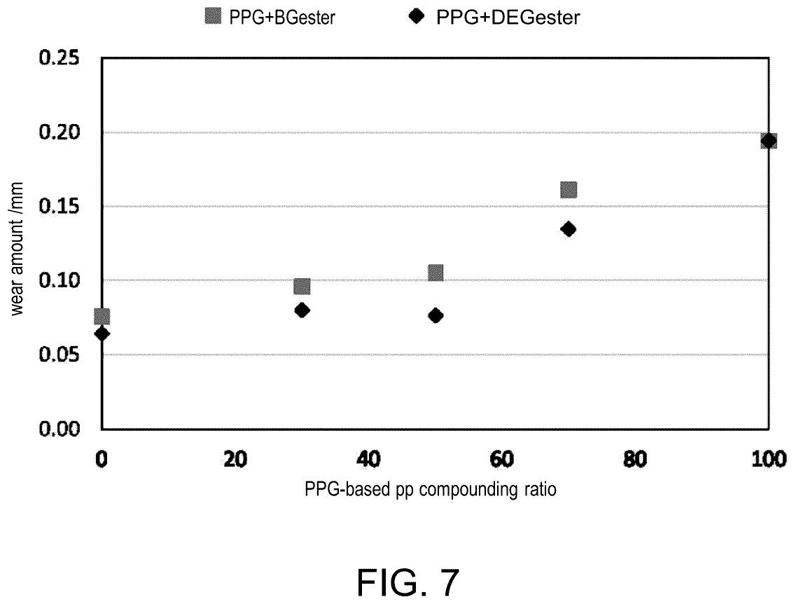

A wear test was performed on the obtained polishing pads using a small friction and wear tester under the following conditions. In FIG. 7, the wear amount (thickness) is indicated along the vertical axis, and the PPG compounding ratio is indicated along the horizontal axis.

### (Wear Test Conditions)

Polishing machine used: Small friction and wear tester
Indenter side: PAD (17ϕ)
Surface plate side: #180 sandpaper
Load: 300 g
Liquid: Water
Flow rate: 45 ml/min.
Surface plate rotation speed: 40 rpm
Time: 10 min.
Thickness measurement load: 300 g

As is clear from FIG. 7, when the PPG compounding ratio in the high-molecular-weight polyol increases, the wear amount becomes large, and the wear resistance deteriorates. In a case where the compounding ratio of PPG is less than 60 weight %, an increase in the wear amount is suppressed. On the other hand, when the compounding ratio of PPG exceeds 60 weight %, the wear amount abruptly increases. This tendency is the same for both the esters A and B. In addition, in a case where the compounding ratio is less than 60 weight %, the wear amount was approximately the same as that of the polishing pad (0.10 mm) of Comparative Example 4, which was conventionally well known.

In polishing pads for which the compounding ratios of the esters A and B were set to 100%, the step elimination performance, which will be described below, was poor.

### (Polishing Performance Evaluation)

Polishing tests were performed using the obtained polishing pads of Example 1, Comparative Example 1 and Comparative Example 4 under the following polishing conditions.

### (Polishing Conditions)

Polishing machine used: F-REX300X (manufactured by Ebara Corporation)
Disk: A188 (manufactured by 3M Company)
Abrasive temperature: 20° C.
Polishing surface plate rotation speed: 85 rpm
Polishing head rotation speed: 86 rpm
Polishing pressure: 3.5 psi
Polishing slurry (metal film): CSL-9044C (a liquid mixture of CSL-9044C undiluted solution and pure water in a weight ratio of 1:9 was used) (manufactured by Fujimi Corporation)
Polishing slurry flow rate: 200 ml/min.
Polishing time: 60 sec.
Item to be polished (metal film): Cu film substrate
Pad break: 35 N 10 min.
Conditioning: Ex-situ, 35 N, 4 scan

### (Step Elimination Performance Test)

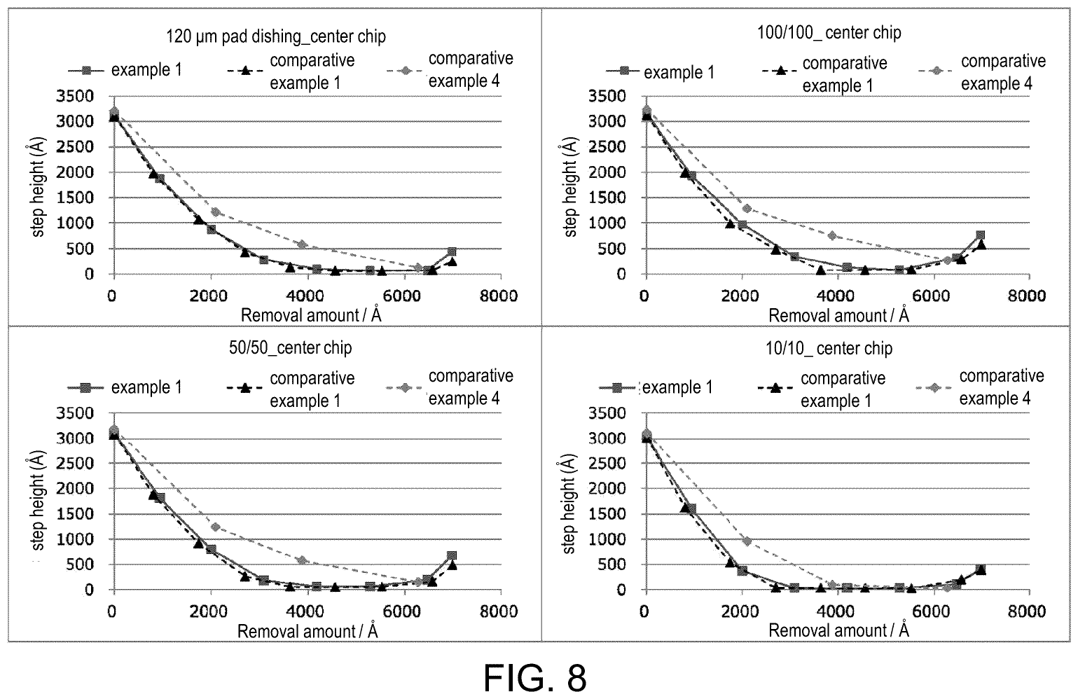

The polishing pad was installed at a predetermined position in a polishing device through double-sided tape having an acrylic adhesive, and a polishing process was performed under the above-described polishing conditions. The step elimination performance was evaluated by measuring 100 μm/100 μm dishing with a step/surface roughness/fine shape measuring instrument (manufactured by KLA-Tencor Corporation, P-16+). The evaluation results are shown in FIG. 8.

Polishing was performed on a patterned wafer having a 7000-angstrom film thickness and 3000-angstrom steps at a polishing rate adjusted so that the polishing amount each time reached 1000 angstroms, polishing was performed stepwise, and the steps on the wafer were measured each time. “Step hight” along the vertical axis indicates steps.

In FIG. 8, 120 μm in the upper left view indicates polishing of a wiring having a wiring width of 120 μm, 100/100 in the upper right view indicates a wiring in which the width of an insulating film was 100 μm with respect to a Cu wiring width of 100 μm, 50/50 in the lower left view indicates a wiring in which the width of an insulating film was 50 μm with respect to a Cu wiring width of 50 μm, 10/10 in the lower right view indicates a wiring in which the width of an insulating film was 10 μm with respect to a Cu wiring width of 10 μm, and the wirings become finer as the numbers become smaller.

### (Defect Performance Evaluation)

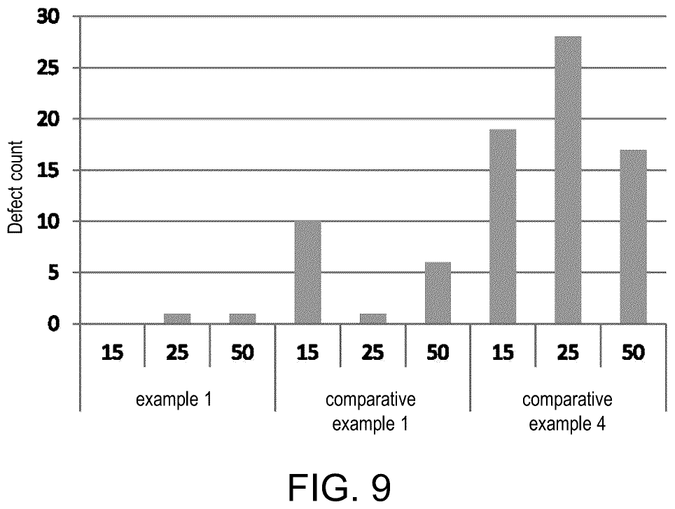

Defects (surface defects) that were 90 nm or greater were detected using a high-sensitivity measurement mode of a surface inspection device (manufactured by KLA Corporation, SURFSCAN SP2XP) from the 15^{th}, 25^{th} and 50^{th} polished substrates. Regarding each of the detected defects, analysis was performed on SEM images captured using a review SEM, and the number of scratches was measured. The results are shown in FIG. 9.

As is clear from FIG. 8, the polishing pad of Example 1 had a faster step elimination rate than the polishing pad of Comparative Example 4, which was conventionally well known, and had almost the same step elimination performance as that of the polishing pad of Comparative Example 1 having excellent step elimination performance.

In addition, as is clear from FIG. 9, in the polishing pad of Example 1, the number of scratches more significantly decreased than those of the polishing pad of Comparative Example 4, which was conventionally well known, and the polishing pad of Comparative Example 1, and excellent defect performance was exhibited.

While Examples 2 to 4 are not shown in the drawings, the step elimination performance and the defect performance were equivalent to those of Example 1.

### Embodiment 2

### (Manufacturing of Polishing Layer)

3.5 Parts of unexpanded hollow microspheres each having a shell part composed of an acrylonitrile-vinylidene chloride copolymer and containing an isobutane gas in the shell were added to and mixed with 100 parts of an isocyanate-terminated urethane prepolymer having an NCO equivalent of approximately 520 that had been obtained by mixing 2,4-tolylene diisocyanate (TDI) and a high-molecular-weight polyol so that the proportions became as shown in Table 2, preparing PP1 and PP2, respectively, and mixing them so that the proportions became as shown in Table 3, thereby obtaining a liquid mixture. The obtained liquid mixture was charged into a first liquid tank and kept warm. Next, separately from a first liquid, 23.1 parts of MOCA was charged into a second liquid tank as a curing agent and kept warm in the second liquid tank. The respective liquids in the first liquid tank and the second liquid tank were injected into a mixer equipped with two inlets such that an R value, which indicates the equivalence ratio at each inlet of an amino group and a hydroxyl group present in the curing agent with respect to a terminal isocyanate group in the prepolymer, reached 0.90. The two injected liquids were injected into a mold of a molding machine preheated to 80° C. while being mixed and stirred, then, the mold was clamped, and a molding was heated for 30 minutes and primarily cured. The primarily-cured molding was released from the mold and then secondarily cured in an oven at 120° C. for four hours, thereby obtaining a urethane molding. The obtained urethane molding was naturally cooled to 25° C., then, heated again in the oven at 120° C. for five hours and then sliced in a thickness of 1.3 mm, thereby obtaining each of polishing layers 8-11.

### <Manufacturing of Cushion Layer>

A non-woven fabric composed of polyester fibers was immersed in a urethane resin solution (manufactured by DIC Corporation, trade name “C1367”). After the immersion, the resin solution was squeezed using a mangle roller capable of pressurization between a pair of rollers to substantially uniformly impregnate the non-woven fabric with the resin solution. Next, the non-woven fabric was immersed in a coagulating liquid composed of water of room temperature to coagulate and regenerate the impregnating resin, thereby obtaining a resin-impregnated non-woven fabric. After that, the resin-impregnated non-woven fabric was removed from the coagulating liquid, furthermore, immersed in a washing liquid composed of water to remove N,N-dimethylformamide (DMF) in the resin and then dried. After the drying, a skin layer on the surface was removed by a buffing treatment to produce a 1.3 mm-thick cushion layer.

### Examples and Comparative Examples

Each of the polishing layers 8-11 and the cushion layer were joined with 0.1 mm-thick double-sided tape (tape including adhesives composed of an acrylic resin on both surfaces of a PET base material).

In Table 2, TDI is 2,4-toluene diisocyanate, PPG1000 is a polypropylene glycol having a number-average molecular weight of 1000, and ester is a polyester diol having a number-average molecular weight of 1000 obtained by reacting adipic acid and butanediol.

TABLE 2

| Isocyanate-terminated | | | |
|---|---|---|---|
| urethane prepolymer | Equivalent | Composition | Note |
| PP1 | 521.9 | TDI/PPG1000/ | Low-hardness |
| | | DEG | PPG-based PP |
| PP2 | 520.7 | TDI/ester/DEG | Low-hardness |
| | | | polyester-based |
| | | | PP (in ester group |
| | | | concentration) |

TDI: 2,4-Toluene diisocyanate
PPG1000: Polypropylene glycol having a number-average molecular weight of 1000
DEG: Diethylene glycol
ester: Butanediol adipate-based ester having a molecular weight of 1000

TABLE 3

| | | | PPG |
|---|---|---|---|
| | Formulation | | compounding |
| | PP | Curing agent | ratio |
| Polishing layer 8 | PP1:PP2 = 50:50 | MOCA | 50 |
| Polishing layer 9 | PP1:PP2 = 30:70 | | 30 |
| Polishing layer 10 | PP1:PP2 = 100:0 | | 100 |
| Polishing layer 11 | PP1:PP2 = 0:100 | | 0 |

### (Pulse NMR Measurement)

On the polishing layers 8-11, pulse NMR measurement was performed under the following conditions. Depending on relaxation times, the polishing layer were divided into a crystalline phase, an intermediate phase and an amorphous phase, and the proportion of each was calculated. The results are summarized in Table 4 and Table 5.

Device Minispec mq20 (20 MHz) manufactured by Bruker
Nuclide ¹H
Measurement T₂
Measurement method Solid echo method
Acquisition Scale 0.4 msec
Scan 128 times
Recycle Delay 0.5 sec
Measurement temperature40° C. and 80° C.

After 60 minutes from a moment when the device temperature reached the measurement temperature and a sample was set therein, the measurement began. As the sample, a sample tube filled with 10 sample pellets (8 mmϕ, approximately 50 mg) prepared with the above-described device under the above-described polishing conditions was used.

TABLE 4

| | 40° C. | | | | | |
|---|---|---|---|---|---|---|
| | CC40 | IC40 | NC40 | T(1) | T(2) | T(3) |
| Polishing layer 8 | 37.8 | 36.4 | 25.9 | 0.014 | 0.041 | 0.137 |
| Polishing layer 9 | 39.5 | 35.1 | 25.4 | 0.014 | 0.042 | 0.153 |
| Polishing layer 10 | 32.6 | 37.1 | 30.3 | 0.014 | 0.044 | 0.115 |
| Polishing layer 11 | 40.6 | 31.8 | 27.6 | 0.014 | 0.042 | 0.179 |
| | 80° C. | | | | | |
| | CC80 | IC80 | NC80 | T(1) | T(2) | T(3) |
| Polishing layer 8 | 20.3 | 22.5 | 57.2 | 0.016 | 0.061 | 0.244 |
| Polishing layer 9 | 20.8 | 21.9 | 57.3 | 0.015 | 0.059 | 0.266 |
| Polishing layer 10 | 18.3 | 23.9 | 57.8 | 0.016 | 0.070 | 0.204 |
| Polishing layer 11 | 22.7 | 19.8 | 57.5 | 0.015 | 0.054 | 0.280 |

T(1) in Table 4 indicates the relaxation time corresponding to the crystalline phase, T(2) indicates the relaxation time corresponding to the intermediate phase, and T(3) indicates the relaxation time corresponding to the amorphous phase.

TABLE 5

| | | | (NC80/CC80) − |
|---|---|---|---|
| | NC80/CC80 | NC40/CC40 | (NC40/CC40) |
| Polishing layer 8 | 2.8 | 0.7 | 2.1 |
| Polishing layer 9 | 2.8 | 0.6 | 2.1 |
| Polishing layer 10 | 3.2 | 0.9 | 2.2 |
| Polishing layer 11 | 2.5 | 0.7 | 1.9 |

### (Measurement of Polishing Layer and Polishing Pad)

The characteristics of the polishing layers 8-11 and polishing pads of Examples 5 and 6 and Comparative Examples 5 and 6 for which the polishing layers 8-11 were used were measured. The results are shown in Table 6. Measurement methods are as described below.

TABLE 6

| | | | | | HS | | | Evaluation | | |
|---|---|---|---|---|---|---|---|---|---|---|
| | Polishing | | D | R | distance | | Q value | Wear | | |
| | layer used | Density | hardness | value | (nm) | Transmission | at peak | properties | Step | Defect |
| Example 5 | Polishing | 0.82 | 46.5 | 0.90 | 7.9 | 0.223 | 0.799 | ∘ | ∘ | ∘ |
| | layer 8 | | | | | | | | | |
| Example 6 | Polishing | 0.80 | 45.5 | 0.90 | 8.4 | 0.240 | 0.750 | ∘ | ∘ | ∘ |
| | layer 9 | | | | | | | | | |
| Comparative | Polishing | 0.84 | 49.5 | 0.90 | 9.9 | 0.216 | 0.633 | x | ∘ | ∘ |
| Example 5 | layer 10 | | | | | | | | | |
| Comparative | Polishing | 0.81 | 45.0 | 0.90 | 10.0 | 0.216 | 0.627 | ∘ | x | x |
| Example 6 | layer 11 | | | | | | | | | |

### (Distance Between Hard Segments)

The distances between hard segments of the polishing layers 8-11 were measured under the following measurement conditions based on the contents described above.

### [Measurement Conditions]

Device: BL8S3 (Aichi Synchrotron Radiation Center)
Wavelength: 1.5 angstroms
Measurement detector: R-AXIS IV++
Measurement time: 120 sec.
Measurement camera length: 3976.88 mm

The measurement data of the polishing layer 8 (Example 5) and the polishing layer 10 (Comparative Example 5) are shown in FIG. 3, FIG. 4 and FIG. 5. The distances between hard segments (HS distances) obtained from the data, the values of Q at the peaks at that time and transmissions are shown in Table 3.

### (Density)

The densities (g/cm³) of the polishing layers were measured according to Japanese Industrial Standards (JIS K 6505).

### (D Hardness)

The D hardness of the polishing layers was measured using a D-type hardness meter according to Japanese Industrial Standards (JIS-K-6253). Here, a measurement sample was obtained by overlaying a plurality of the polishing layers as necessary so that the total thickness reached at least 4.5 mm or greater.

### (Wear Test)

A wear test was performed on the obtained polishing pads using a small friction and wear tester under the following conditions. Regarding the obtained wear test results, in Table 6, when the wear amount was 0.15 mm or less, ‘o’ was entered, and, when the wear amount exceeded 0.15 mm, ‘x’ was entered.

### (Wear Test Conditions)

Polishing machine used: Small friction and wear tester
Indenter side: PAD (170)
Surface plate side: #180 sandpaper
Load: 300 g
Liquid: Water
Flow rate: 45 ml/min.
Surface plate rotation speed: 40 rpm
Time: 10 min.
Thickness measurement load: 300 g

In Examples 5 and 6 where the distance between hard segments was appropriate, excellent wear performance was exhibited; however, in Comparative Examples 5 and 6 where the polishing layer containing only PPG or only the ester as the high-molecular-weight polyol in the isocyanate-terminated prepolymer was used, the results were not favorable.

Polishing tests were performed under the following polishing conditions using the obtained polishing pads of Examples 5 and 6 and Comparative Examples 5 and 6, and polishing performance (step elimination performance and defect performance) was evaluated.

### (Polishing Conditions)

Polishing machine used: F-REX300X (manufactured by Ebara Corporation)
Disk: A188 (manufactured by 3M Company)
Abrasive temperature: 20° C.
Polishing surface plate rotation speed: 85 rpm
Polishing head rotation speed: 86 rpm
Polishing pressure: 3.5 psi
Polishing slurry (metal film): CSL-9044C (a liquid mixture of CSL-9044C undiluted solution and pure water in a weight ratio of 1:9 was used) (manufactured by Fujimi Corporation)
Polishing slurry flow rate: 200 ml/min.
Polishing time: 60 sec.
Item to be polished (metal film): Cu film substrate
Pad break: 35 N 10 min.
Conditioning: Ex-situ, 35 N, 4 scan

### (Step Elimination Performance Test)

The polishing pad was installed at a predetermined position in a polishing device through double-sided tape having an acrylic adhesive, and a polishing process was performed under the above-described polishing conditions. The step elimination performance was evaluated by measuring dishing with each of the wiring widths of 120 μm/120 μm, 100 μm/100 μm, 50 μm/50 μm and 10 μm/10 μm with a step/surface roughness/fine shape measuring instrument (manufactured by KLA-Tencor Corporation, P-16+).

Polishing was performed on a patterned wafer having a 7000-angstrom film thickness and 3000-angstrom steps at a polishing rate adjusted so that the polishing amount each time reached 1000 angstroms, polishing was performed stepwise, and the steps on the wafer were measured each time. In all of the wiring widths, when the polishing amount was 6000 angstroms or less and steps were eliminated, ‘o’ was entered, and, when steps were eliminated after the polishing amount exceeded 6000 angstroms or steps were not eliminated, ‘x’ was entered.

### (Defect Performance Evaluation)

Defects (surface defects) that were 155 nm or greater were detected using a high-sensitivity measurement mode of a surface inspection device (manufactured by KLA Corporation, SURFSCAN SP2XP) from the 16^{th}, 26^{th} and 51^{th} polished substrates. Regarding each of the detected defects, analysis was performed on SEM images captured using a review SEM, and the number of scratches was measured. When the number of scratches was 10 or less, which was considered to be practically required, ‘o’ was entered, and, when the number of scratches exceeded 10, ‘x’ was entered.

### INDUSTRIAL APPLICABILITY

The present invention contributes to the manufacturing and sale of polishing pads and is thus industrially applicable.

### REFERENCE SIGNS LIST

1 Polishing device
3 Polishing pad
4 Polishing layer
4A Hollow microsphere
6 Cushion layer
7 Adhesive layer
8 Item to be polished
9 Slurry
Polishing surface plate

1. A polishing pad comprising:
a polishing layer composed of a polyurethane resin foam derived from an isocyanate-terminated prepolymer and a curing agent,
wherein a distance between hard segments in the polishing layer as measured by small-angle X-ray scattering is 9.5 nm or less.

2. The polishing pad according to claim 1,
wherein the isocyanate-terminated prepolymer includes a polyisocyanate compound-derived configuration unit and a high-molecular-weight polyol-derived configuration unit, and
the high-molecular-weight polyol-derived configuration unit is composed of at least a polypropylene glycol configuration unit and a polyester diol configuration unit.

3. The polishing pad according to claim 2,
wherein there is less than 60 weight % of the polypropylene glycol configuration unit with respect to the high-molecular-weight polyol-derived configuration unit.

4. The polishing pad according to claim 2,
wherein a polyester diol for forming the polyester diol configuration unit has a number-average molecular weight of 600-2500.

5. The polishing pad according to claim 1,
wherein an average bubble diameter in the polyurethane resin foam is 5 μm or more and less than 20 μm.

6. The polishing pad according to claim 1,
wherein the isocyanate-terminated prepolymer has an NCO equivalent of 500-600.

7. The polishing pad according to claim 1,
wherein the distance between the hard segments in the polishing layer as measured by small-angle X-ray scattering is 3.0-9.5 nm.

8. A method for manufacturing a polishing pad having a polishing layer composed of a polyurethane resin foam, the method comprising:
a step of mixing and reacting an isocyanate-terminated prepolymer and a curing agent to obtain the polyurethane resin foam; and
a step of molding the polyurethane resin foam into a shape of the polishing layer,
wherein a distance between hard segments in the polishing layer as measured by small-angle X-ray scattering is 9.5 nm or less.

9. The method for manufacturing a polishing pad according to claim 8,
wherein an unexpanded balloon is made to coexist at the time of mixing the isocyanate-terminated prepolymer and the curing agent.

10. A polishing pad comprising:
a polishing layer composed of a polyurethane resin foam derived from an isocyanate-terminated prepolymer and a curing agent,
wherein a ratio (NC80/CC80) of a content proportion by weight (NC80) of an amorphous phase in the polishing layer as measured by pulse NMR at 80° C. to a content proportion by weight (CC80) of a crystalline phase in the polishing layer as measured by pulse NMR at 80° C. is 2.6-3.1, and
a ratio (NC40/CC40) of a content proportion by weight (NC40) of the amorphous phase in the polishing layer as measured by pulse NMR at 40° C. to a content proportion by weight (CC40) of the crystalline phase in the polishing layer as measured by pulse NMR at 40° C. is 0.5-0.9.

11. The polishing pad according to claim 10,
wherein a numerical value that is obtained from Expression (1) below is larger than 1.9 and smaller than 2.2,
[Expression 1]
(NC80/CC80)−(NC40/CC40) (1)

12. The polishing pad according to claim 10,
wherein the CC80 is 19.0-22.0 weight %.

13. The polishing pad according to claim 10,
wherein the NC40 is 22.0-27.0 weight %.

14. The polishing pad according to claim 10,
wherein the isocyanate-terminated prepolymer includes a polyisocyanate compound-derived configuration unit and a high-molecular-weight polyol-derived configuration unit, and
the high-molecular-weight polyol-derived configuration unit is composed of at least a polypropylene glycol configuration unit and a polyester diol configuration unit.

15. The polishing pad according to claim 14,
wherein there is less than 60 weight % of the polypropylene glycol configuration unit with respect to the high-molecular-weight polyol-derived configuration unit.

16. The polishing pad according to claim 14,
wherein a polyester diol for forming the polyester diol configuration unit has a number-average molecular weight of 600-2500.

17. The polishing pad according to claim 10,
wherein the isocyanate-terminated prepolymer has an NCO equivalent of 500-600.

18. A method for manufacturing a polishing pad having a polishing layer composed of a polyurethane resin foam, the method comprising:
a step of mixing and reacting an isocyanate-terminated prepolymer and a curing agent to obtain the polyurethane resin foam; and
a step of molding the polyurethane resin foam into a shape of the polishing layer,
wherein a ratio (NC80/CC80) of a content proportion by weight (NC80) of an amorphous phase in the polishing layer as measured by pulse NMR at 80° C. to a content proportion by weight (CC80) of a crystalline phase in the polishing layer as measured by pulse NMR at 80° C. is 2.6-3.1, and
a ratio (NC40/CC40) of a content proportion by weight (NC40) of the amorphous phase in the polishing layer as measured by pulse NMR at 40° C. to a content proportion by weight (CC40) of the crystalline phase in the polishing layer as measured at 40° C. is 0.5-0.9.

19. A polishing pad comprising:
a polishing layer composed of a polyurethane resin foam derived from an isocyanate-terminated prepolymer and a curing agent,
wherein the isocyanate-terminated prepolymer includes a polyisocyanate compound-derived configuration unit and a high-molecular-weight polyol-derived configuration unit,
the high-molecular-weight polyol-derived configuration unit is composed of at least a polypropylene glycol configuration unit and a polyester diol configuration unit, and
there is less than 60 weight % of the polypropylene glycol configuration unit with respect to the high-molecular-weight polyol-derived configuration unit.

20. The polishing pad according to claim 19,
wherein there is 30-50 weight % of the polypropylene glycol configuration unit with respect to the high-molecular-weight polyol-derived configuration unit.

21. The polishing pad according to claim 19,
wherein the polyester diol configuration unit is derived from a polyester diol having a number-average molecular weight of 600-2500.

22. A method for manufacturing a polishing pad having a polishing layer composed of a polyurethane resin foam, the method comprising:
a step of reacting a polyisocyanate compound and a high-molecular-weight polyol containing at least a polypropylene glycol and a polyester diol to obtain an isocyanate-terminated prepolymer;
a step of reacting the isocyanate-terminated prepolymer and a curing agent to obtain the polyurethane resin foam; and
a step of molding the polyurethane resin foam into a shape of the polishing layer,
wherein there is less than 60 weight % of the polypropylene glycol with respect to a total amount of the high-molecular-weight polyol.
